(19) United States
(12) Patent Application Publication
(10) Pub. No.: US 2025/0006578 A1
(43) Pub. Date: Jan. 2, 2025

(54) PACKAGE STRUCTURE WITH CAVITY AND RELATED PACKAGING METHOD

(71) Applicant: JCET GROUP CO., LTD., Jiangsu (CN)

(72) Inventors: Jianghua Zhang, Jiangsu (CN); Xianfang Yang, Jiangsu (CN); Hua Zhou, Jiangsu (CN); Yue Zhou, Jiangsu (CN); Peng Li, Jiangsu (CN); Hengli Tang, Jiangsu (CN); Junjun Li, Jiangsu (CN)

(73) Assignee: JCET GROUP CO., LTD., Jiangsu (CN)

(21) Appl. No.: 18/748,034

(22) Filed: Jun. 19, 2024

(30) Foreign Application Priority Data
Jun. 30, 2023 (CN) 202310803692.2

(51) Int. Cl. H01L 23/31; H01L 21/56; H01L 23/00; H01L 23/538; H01L 23/552; H01L 25/00; H01L 25/065

(52) U.S. Cl. CPC H01L 23/315; H01L 21/56; H01L 23/3157; H01L 23/5383; H01L 23/552; H01L 24/16; H01L 25/0655; H01L 25/50; H01L 2224/16225

(57) ABSTRACT

The present disclosure relates to the field of packaging technology, and discloses a package structure with a cavity and a related packaging method. A first encapsulation body arranged on a surface of a substrate is covered by using an encapsulation layer including a first encapsulation layer and a second encapsulation layer, and a cavity is formed between the first encapsulation body and the substrate; and a material corresponding to the first encapsulation layer has a fluidity greater than that of a material corresponding to the second encapsulation layer, so that the first encapsulation layer is positioned on an edge of an inner part of the cavity and the surface of the substrate of an outer part of the cavity, and the second encapsulation layer is positioned on the surface of the first encapsulation layer of an outer part of the cavity.

### CROSS-REFERENCE TO RELATED APPLICATION

This application claims the priority benefit of China application serial no. 202310803692.2, filed on Jun. 30, 2023. The entirety of the above-mentioned patent application is hereby incorporated by reference herein and made a part of this specification.

### TECHNICAL FIELD

The present disclosure relates to the field of packaging technology, and specifically to a package structure with a cavity and a related packaging method.

### BACKGROUND

In an encapsulated product, a cavity is required to be left between an encapsulation body and a substrate during encapsulation, and the cavity cannot be contaminated by an encapsulant. In order to avoid the contamination of the cavity by the encapsulant, the encapsulant with a poor fluidity and a high viscosity is generally used; however, a bonding force between the encapsulant and the substrate is poor, and the poor product reliability is easily caused.

### SUMMARY

The present disclosure provides a package structure with a cavity and a related packaging method, which aims to solve poor reliability of an existing package structure with a cavity.

To achieve the above objective, the present disclosure provides a package structure with a cavity, which includes:
a substrate;
a first encapsulation body arranged on a surface of the substrate through a first connection structure;
an encapsulation layer covering one side of the substrate provided with the first encapsulation body;
where a cavity is provided between the first encapsulation body and the substrate, and the encapsulation layer includes a first encapsulation layer positioned on the surface of the substrate and a second encapsulation layer positioned on a surface of the first encapsulation layer and covering the first encapsulation body; and
a material corresponding to the first encapsulation layer has a fluidity greater than that of a material corresponding to the second encapsulation layer, so that the first encapsulation layer is positioned on an edge of an inner part of the cavity and the surface of the substrate of an outer part of the cavity, and the second encapsulation layer is positioned on the surface of the first encapsulation layer of an outer part of the cavity.

Preferably, the first encapsulation layer has a thickness less than or equal to a height of one side surface of the first encapsulation body facing the substrate from the surface of the substrate.

Preferably, the package structure with a cavity further includes:
a second encapsulation body arranged on the surface of the substrate through a second connection structure;
where an area of one side surface of the first encapsulation body facing the substrate is greater than that of one side surface of the second encapsulation body facing the substrate, a height of one side surface of the first encapsulation body facing the substrate from the surface of the substrate is greater than or equal to a height of one side surface of the second encapsulation body facing the substrate from the surface of the substrate, and the first encapsulation layer is filled between the second encapsulation body and the surface of the substrate.

Preferably, the first encapsulation layer has a thickness greater than or equal to a height of one side surface of the second encapsulation body facing the substrate from the surface of the substrate.

Preferably, the first encapsulation body is a chip, and the second encapsulation body is an electronic component.

Preferably, both the first connection structure and the second connection structure are metal pillars.

Preferably, one side surface of the first encapsulation body facing the substrate is provided with a sensing area, and the cavity is provided between the sensing area and the surface of the substrate.

Preferably, the sensing area is positioned in a middle area of one side surface of the first encapsulation body facing the substrate.

Preferably, the package structure with a cavity further includes:
an electromagnetic shielding layer arranged on the surface of the encapsulation layer.

Correspondingly, the present disclosure further provides a preparation method of a package structure with a cavity, which includes:
providing a substrate;
arranging a first encapsulation body on the surface of the substrate through a first connection structure;
covering an encapsulation layer on one side of the substrate provided with the first encapsulation body, so that a cavity is formed between the first encapsulation body and the substrate;
where the encapsulation layer includes a first encapsulation layer positioned on the surface of the substrate and a second encapsulation layer positioned on a surface of the first encapsulation layer and covering the first encapsulation body; and
a material corresponding to the first encapsulation layer has a fluidity greater than that of a material corresponding to the second encapsulation layer, so that the first encapsulation layer is positioned on an edge of an inner part of the cavity and the surface of the substrate of an outer part of the cavity, and the second encapsulation layer is positioned on the surface of the first encapsulation layer of an outer part of the cavity.

Preferably, the first encapsulation layer has a thickness less than or equal to a height of one side surface of the first encapsulation body facing the substrate from the surface of the substrate.

Preferably, after providing a substrate, and before covering an encapsulation layer on one side of the substrate provided with the first encapsulation body, the method further includes:
arranging a second encapsulation body on the surface of the substrate through a second connection structure;
where an area of one side surface of the first encapsulation body facing the substrate is greater than that of one side surface of the second encapsulation body facing the substrate, a height of one side surface of the first encapsulation body facing the substrate from the surface of the substrate is greater than or equal to a height of one side surface of the second encapsulation body facing the substrate from the surface of the substrate, and the first encapsulation layer is filled between the second encapsulation body and the surface of the substrate when the encapsulation layer is formed later.

Preferably, the first encapsulation layer has a thickness greater than or equal to a height of one side surface of the second encapsulation body facing the substrate from the surface of the substrate.

Preferably, the first encapsulation body is a chip, and the second encapsulation body is an electronic component.

Preferably, one side surface of the first encapsulation body facing the substrate is provided with a sensing area, and the cavity is provided between the sensing area and the surface of the substrate.

Preferably, the sensing area is positioned in a middle area of one side surface of the first encapsulation body facing the substrate.

Preferably, the covering an encapsulation layer on one side of the substrate provided with the first encapsulation body includes:
when the encapsulation layer is in a fluid state, pressing the first encapsulation body arranged on the substrate into the encapsulation layer facing the first encapsulation layer; and
curing the encapsulation layer after the first encapsulation layer reaches the surface of the substrate, thereby forming the encapsulation layer covering one side of the substrate provided with the first encapsulation body.

Preferably, after forming the encapsulation layer, the method further includes:
performing cutting based on a cutting process to obtain a single package structure.

Preferably, after obtaining a single package structure, the method further includes:
forming an electromagnetic shielding layer on a surface of an encapsulation layer of the single package structure.

The present disclosure has the following beneficial effects that: the present disclosure provides a package structure with a cavity and a related packaging method, where a first encapsulation body arranged on a surface of a substrate is covered by a first encapsulation layer and a second encapsulation layer, and a cavity is formed between the first encapsulation body and a first connection structure; a material corresponding to the first encapsulation layer has a fluidity greater than that of a material corresponding to the second encapsulation layer, so that the first encapsulation layer is positioned on an edge of an inner part of the cavity and the surface of the substrate of an outer part of the cavity, and the second encapsulation layer is positioned on the surface of the first encapsulation layer of an outer part of the cavity, which not only increases a bonding force between the encapsulation layer and the substrate and improves the reliability of the product, but also allows the cavity to be retained and provides the function of the cavity.

The second encapsulation body is arranged on the substrate, and the first encapsulation layer is filled between the second encapsulation body and the surface of the substrate, so that the different packaging requirements of two encapsulation bodies are met, and the reliability of a product is improved.

### BRIEF DESCRIPTION OF DRAWINGS

FIG. 1 is an exemplary package structure according to an embodiment to introduce a technical problem.

FIG. 2 is an exemplary package structure according to an embodiment to introduce another technical problem.

FIG. 3 is a schematic diagram of a package structure according to an embodiment.

FIG. 4 is a schematic diagram of another package structure according to an embodiment.

FIGS. 5 to 13 are schematic diagrams of a preparation process of a package structure according to an embodiment.

FIG. 14 is a schematic diagram of a package structure according to an embodiment provided with an electromagnetic shielding layer.

### DETAILED DESCRIPTION OF EMBODIMENTS

The following clearly and completely describes the technical solutions in embodiments of the present disclosure with reference to the accompanying drawings in embodiments of the present disclosure. It is clear that the described embodiments are merely a part rather than all of embodiments of the present disclosure. Based on the embodiments of the present disclosure, all other embodiments obtained by those of ordinary skill in the art without creative effort fall within the protection scope of the present disclosure.

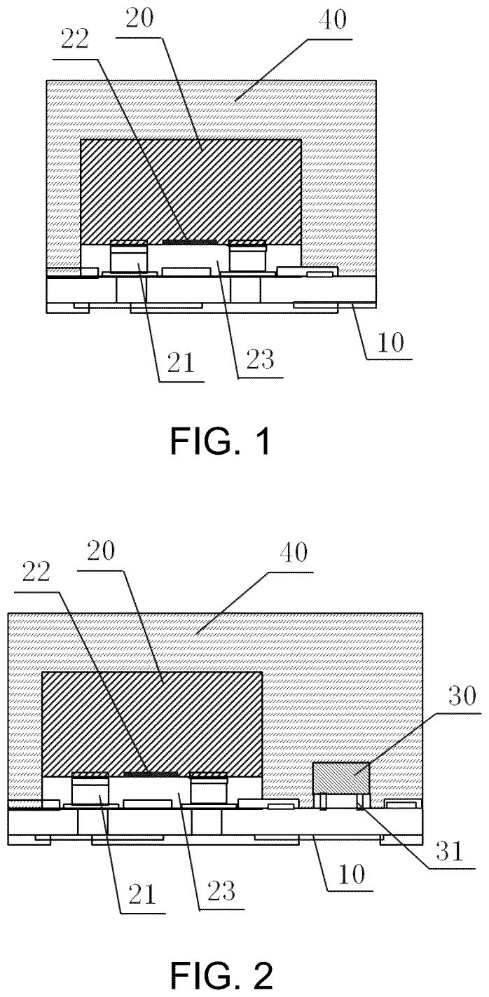

Referring to FIG. 1, a substrate 10, a first encapsulation body 20 positioned on a surface of the substrate 10, and an encapsulant 40 encapsulating the first encapsulation body 20 are provided. The first encapsulation body 20 is arranged on the surface of the substrate 10 through a first connection structure 21, one side surface of the first encapsulation body 20 facing the substrate is provided with a sensing area 22, and a cavity 23 is provided between the first encapsulation body 20 and the substrate 10. In order to retain the cavity 23 and prevent the encapsulant 40 from contaminating the sensing area 22, an encapsulant 40 with a poor fluidity and a high viscosity is generally used; however, a bonding force between the encapsulant 40 and the substrate 10 is poor, and the poor product reliability is easily caused.

At present, encapsulation is generally achieved by dry film lamination. The dry film has a fluidity worse than that of a molding compound, which not only increases costs, but also causes unevenness such as bulges on a product surface due to the high viscosity and poor fluidity, thus affecting product reliability.

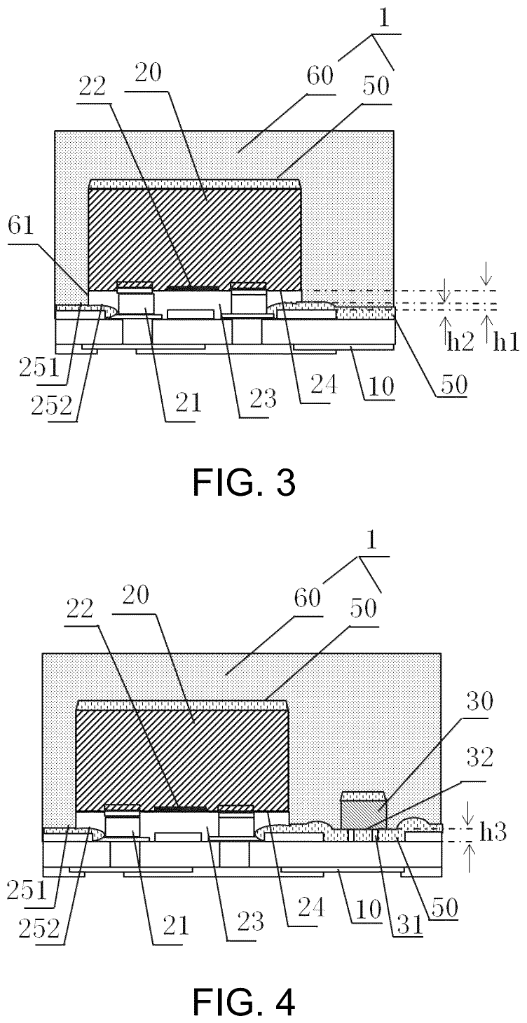

Therefore, in order to solve the above problem, referring to FIG. 3, this embodiment provides a package structure with a cavity, which includes:
a substrate 10;
a first encapsulation body 20 arranged on a surface of the substrate 10 through a first connection structure 21;
an encapsulation layer 1 covering one side of the substrate 10 provided with the first encapsulation body 20;
where a cavity 23 is provided between the first encapsulation body 20 and the substrate 10, and the encapsulation layer 1 includes a first encapsulation layer 50 positioned on the surface of the substrate 10 and a second encapsulation layer 60 positioned on a surface of the first encapsulation layer 50 and covering the first encapsulation body 20; and
a material corresponding to the first encapsulation layer 50 has a fluidity greater than that of a material corresponding to the second encapsulation layer 60, so that the first encapsulation layer 50 is positioned on an edge 252 of an inner part of the cavity and the surface of the substrate 10 of an outer part 251 of the cavity, and the second encapsulation layer 60 is positioned on the surface of the first encapsulation layer 50 of the outer part 251 of the cavity.

In some embodiments, the package structure with a cavity may be a hollow electronic device with a cavity, such as a surface acoustic wave (SAW) filter, a pressure sensor, a vibration sensor, a micro electro mechanical system (MEMS), a surface acoustic wave device, or the like.

In some embodiments, the substrate 10 may be a resin substrate, a ceramic substrate, a glass substrate, a silicon substrate, a printed circuit board (PCB), a metal substrate, a semiconductor wafer, or the like.

In some embodiments, the substrate 10 is provided with a line, the line may be of a single-layer or multi-layer structure, and the line may include a metal line, a via interconnection structure electrically connected to the metal line, and the like.

The surface of the substrate 10 is provided with a pad connected to the line, the pad is made of metal, and the metal may be one or more of aluminum, nickel, tin, tungsten, platinum, copper, titanium, chromium, tantalum, gold and silver.

In some embodiments, the first encapsulation body 20 may be a chip, specifically, which may be an encapsulation body such as a filter chip, a pressure sensor chip, a vibration sensor chip or the like that is required to be arranged on the surface of the substrate and required to form a cavity with the surface of the substrate.

In some embodiments, one side surface 24 of the first encapsulation body 20 facing the substrate 10 is provided with a sensing area 22, and in order to prevent the sensing area 22 from being contaminated, the cavity 23 is provided between the sensing area 22 and the surface of the substrate 10. Optionally, the sensing area 22 is provided in a middle area of the side surface 24 of the first encapsulation body 20 facing the substrate 10.

In this embodiment, the cavity 23 prevents the encapsulation layer 1 from contaminating the sensing area 22, thereby avoiding affecting the sensing performance.

In some embodiments, the first connection structure 21 may include one or more of a metal ball, a metal bump, a metal pillar and the like, and the first connection structure 21 is fixed to a pad on the surface of the substrate 10 by soldering, so as to electrically connect the first encapsulation body 20 and the substrate 10.

In some embodiments, the metal ball, metal pillar and metal bump are made of one or more of aluminum, nickel, tin, tungsten, platinum, copper, titanium, chromium, tantalum, gold and silver; the metal ball may be a tin ball, and the tin ball may be made of one or more of tin, tin-silver, tin-lead, tin-silver-copper, tin-silver-zinc, tin-zinc, tin-bismuth-indium, tin-indium, tin-gold, tin-copper, tin-zinc-indium, tin-silver-antimony, or the like.

In some embodiments, a material corresponding to the encapsulation layer 1 may be a thermosetting encapsulant or other molding compounds with the characteristics of the thermosetting encapsulant, and the thermosetting encapsulant is initially a solid state, may be softened into a fluid state during first heating, and then cured when heated to a certain temperature; where the thermosetting encapsulant can be phenolic resin, urea-formaldehyde resin, melamine-formaldehyde resin, epoxy resin, unsaturated resin, polyurethane, polyimide, and the like.

In other embodiments, the material corresponding to the encapsulation layer 1 may also be an encapsulant that is initially in a fluid state and is cured after heating.

In some embodiments, a method of covering the first encapsulation body 20 by the encapsulation layer 1 is not particularly limited, for example, may be performed by a method of retaining a cavity 23 between the first encapsulation body 20 and the surface of the substrate 10 using a hot pressing process.

In some embodiments, when the encapsulation layer 1 covers the first encapsulation body 20, referring to FIG. 3, the encapsulation layer 1 includes a first encapsulation layer 50 on the surface of the substrate 10 and a second encapsulation layer 60 on the surface of the first encapsulation layer, the second encapsulation layer 60 has a thickness greater than that of the first encapsulation layer 50, and when the covering is performed by using a hot pressing process or the like, the surface of the first encapsulation body 20 is also covered with the first encapsulation layer 50, so as to improve the bonding force between the encapsulation layer 1 and the first encapsulation body 20. Specifically, one side surface of the first encapsulation body 20 far away from the substrate 10 is also covered with the first encapsulation layer 50, and the second encapsulation layer 60 is positioned on the surface of the first encapsulation layer 50.

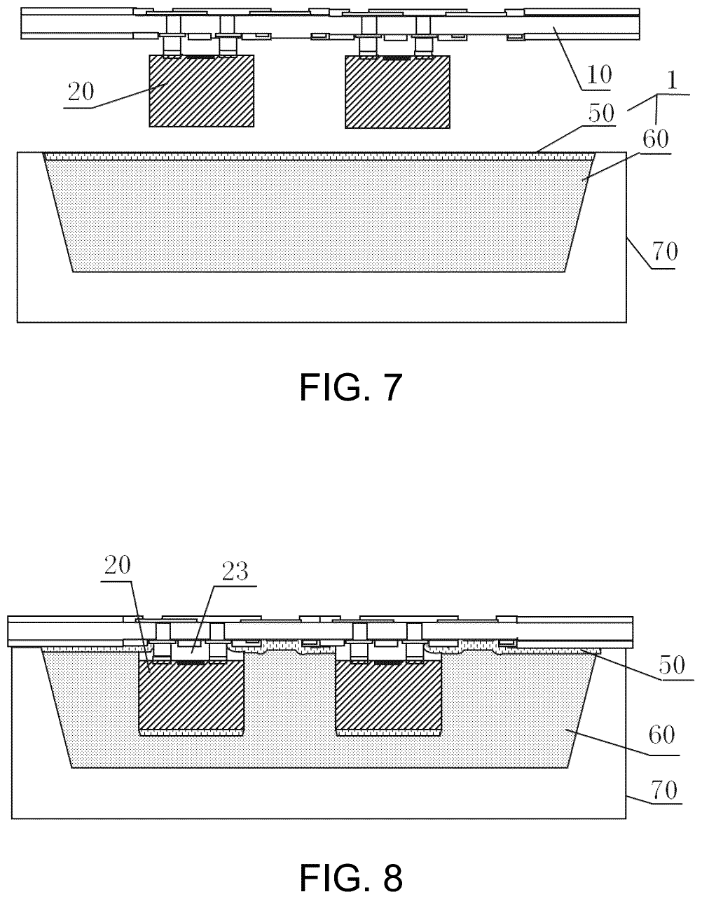

Specifically, in order to retain the cavity 23 between the first encapsulation body 20 and the surface of the substrate 10, when the thermosetting encapsulant is used, the hot pressing process includes:
referring to FIG. 7, providing an encapsulation layer 1, where the encapsulation layer 1 includes a first encapsulation layer 50 and a second encapsulation layer 60 positioned on a surface of the first encapsulation layer 50;
heating the encapsulation layer 1 to enable the encapsulation layer 1 to be in a fluid state;
pressing a first encapsulation body 20 arranged on the substrate 10 into the encapsulation layer 1 facing the first encapsulation layer 50 when the encapsulation layer 1 is in a fluid state; and
referring to FIG. 8, after the first encapsulation layer 50 reaches the surface of the substrate, covering the first encapsulation body 20, and curing the encapsulation layer 1.

It should be noted that the fluid state means a state in which the encapsulation layer 1 can flow when the first encapsulation body 20 arranged on the substrate 10 is pressed into the encapsulation layer 1 facing the first encapsulation layer 50.

According to the package structure provided by the embodiment, the encapsulation layer 1 includes a first encapsulation layer 50 positioned on the surface of the substrate 10 and a second encapsulation layer 60 positioned on the surface of the first encapsulation layer, and a material corresponding to the first encapsulation layer 50 has a fluidity greater than that of a material corresponding to the second encapsulation layer 60, so that the bonding force between the surface of the substrate 10 and the first encapsulation layer 50 is improved, the bonding force between the entire encapsulation layer 1 and the surface of the substrate 10 is further improved, and the reliability of the product is improved.

According to the package structure provided by the embodiment, a material corresponding to the first encapsulation layer has a fluidity greater than that of a material corresponding to the second encapsulation layer, and the first encapsulation layer has a thickness less than that of the second encapsulation layer, so that a position relationship of the first encapsulation layer 50, the second encapsulation layer 60 and the cavity 23 is as follows: the first encapsulation layer 50 is positioned on an edge 252 of an inner part of the cavity and the surface of the substrate 10 of an outer part 251 of the cavity, and the second encapsulation layer is positioned on the surface of the first encapsulation layer 50 of the outer part 251 of the cavity. It can be seen that the first encapsulation layer can only flow to the surface of the substrate at the edge 252 of the inner part the cavity, while the second encapsulation layer is positioned at the surface of the first encapsulation layer 50 of the outer part 251 of the cavity, so that the cavity 23 is still retained, and the function of the cavity 23 can be provided, that is, the encapsulation layer 1 can be prevented from contaminating the sensing area 22.

In this embodiment, the first encapsulation layer 50 is positioned at the edge 252 of the inner part the cavity and the surface of the substrate 10 of the outer part 251 of the cavity, that is, a part of the first encapsulation layer 50 is positioned in the inner part the cavity and is only distributed at the edge 252 of the inner part the cavity without entering the middle part of the cavity 23, and the first encapsulation layer 50 is also positioned at the surface of the substrate 10 of the outer part 251 of the cavity. In this embodiment, the second encapsulation layer 60 is positioned on the surface of the first encapsulation layer 50 of the outer part of 251 of the cavity, that is, the second encapsulation layer 60 is not positioned in the inner part the cavity 23, but positioned on the surface of the first encapsulation layer 50 of the outer part of 251 of the cavity.

According to the package structure provided by the embodiment, referring to FIG. 3, when the first encapsulation layer 50 has a thickness h2 less than a height h1 of one side surface 24 of the first encapsulation body 20 facing the substrate 10 from the surface of the substrate 10, and a gap is still left between the first encapsulation layer 50 positioned at the edge 252 of the inner part the cavity and the first encapsulation body 20. In order to prevent the second encapsulation layer 60 from flowing into the cavity 23 through the gap, the fluidity of the material corresponding to the second encapsulation layer is adjusted to be less than the fluidity of the material corresponding to the first encapsulation layer, so that the second encapsulation layer 60 is only positioned on the surface of the first encapsulation layer 50 of the outer part of 251 the cavity, and the second encapsulation layer 60 is prevented from being pressed to flow into the cavity 23 due to the large thickness.

It should be noted that when a gap is left between the first encapsulation layer 50 at the edge 252 of the cavity and the first encapsulation body 20, a side wall 61 of the second encapsulation layer 60 facing the cavity 23 may be a cambered surface.

In some embodiments, both the first encapsulation layer 50 and the second encapsulation layer 60 contain a plurality of fillers, and in order to change the fluidity of the material corresponding to the first encapsulant and the material corresponding to the second encapsulant, the fluidity can be changed by changing an amount of the fillers contained in the first encapsulation layer and the second encapsulation layer, or by changing the time during which the first encapsulation layer and the second encapsulation layer are placed in the process flow. It should be noted that, there is a corresponding relationship between the fluidity and viscosity of the material corresponding to the encapsulating layer; specifically, when the fluidity of the encapsulating layer is high, the viscosity of the encapsulating layer is low, and when the fluidity of the encapsulating layer is low, the viscosity of the encapsulating layer is high.

Specifically, when the fluidity of the material corresponding to the first encapsulation layer is greater than that of the material corresponding to the second encapsulation layer, the second encapsulation layer has a high viscosity and a low fluidity, can be filled with a high proportion of particles, has low water absorption and high reliability, and is not easy to enter the cavity; and the first encapsulation layer has a low viscosity and a high fluidity, can only be positioned at the edge 252 of the inner part the cavity due to the thin thickness, and is not easy to enter the cavity corresponding to the sensing area.

In this embodiment, the second encapsulation layer has a thickness greater than that of the first encapsulation layer, so that the encapsulation layer 1 has low overall fluidity, is not easy to enter the cavity, and can well cover the surfaces of the substrate and the chip; meanwhile, the encapsulation layer can enhance the bonding force between the encapsulation layer and the substrate and between the encapsulation layer and the first encapsulation body, thereby enhancing the reliability of the product.

In some embodiments, the first encapsulation layer 50 at the edge 252 of the inner part the cavity has a thickness h2 less than a height h1 of the side surface 24 of the first encapsulation body 20 facing the substrate 10 from the surface of the substrate 10, thereby avoiding contamination of the side surface 24 of the first encapsulation body 20 facing the substrate 10 by the first encapsulation layer 50.

In some embodiments, the height h1 of the side surface 24 of the first encapsulation body 20 facing the substrate 10 from the surface of the substrate 10 can be reduced, so that the first encapsulation layer 50 at the edge 252 of the inner part the cavity has a thickness h2 equal to a height h1 of the side surface 24 of the first encapsulation body 20 facing the substrate 10 from the surface of the substrate 10, so that the first encapsulation layer 50 only contacts the edge of the side surface 24 of the first encapsulation body 20 facing the substrate 10, thereby avoiding the contamination of the sensing area 22 positioned in the middle area.

Further, as shown in FIG. 2, the surface of the substrate 10 is further provided with a second encapsulation body 30; the second encapsulation body 30 is arranged on the surface of the substrate 10 through a second connection structure 31; in this structure, the cavity 23 cannot be contaminated by the encapsulant 40, and the second connection structure 31 between the second encapsulation body 30 and the surface of the substrate 10 needs to be filled with the encapsulant 40, otherwise poor product reliability is easily caused.

The encapsulant 40 is classified into an encapsulant 40 having a low viscosity and a high fluidity and an encapsulant 40 having a high viscosity and a low fluidity based on the fluidity and viscosity. When the encapsulant 40 having a low viscosity and a high fluidity is used, the encapsulant 40 can be filled between the second encapsulation body 30 and the substrate 10, and the encapsulant 40 is also filled into the cavity 23; when an encapsulant with a high viscosity and a low fluidity is used, the encapsulant 40 is not filled into the cavity 23, and the encapsulant 40 is also not filled or is not filled between the second encapsulation body 30 and the substrate 10; consequently, poor product reliability is caused. As shown in FIG. 1, the encapsulant is not filled between the second encapsulation body 30 and the surface of the substrate 10, and the used encapsulant 40 with a high viscosity and a low fluidity will cause the reduced bonding force between the encapsulant 40 and the substrate 10.

Therefore, in order to solve the above problem, referring to FIG. 4, an embodiment further provides a package structure. Based on the structure of FIG. 3, the surface of the substrate 10 further includes:
a second encapsulation body 30 arranged on the surface of the substrate 10 through a second connection structure 31;
where an area of one side surface 24 of the first encapsulation body 20 facing the substrate 10 is greater than that of one side surface 32 of the second encapsulation body 30 facing the substrate 10, a height h1 of one side surface of the first encapsulation body 20 facing the substrate 10 from the surface of the substrate 10 is greater than or equal to a height h3 of one side surface of the second encapsulation body 30 facing the substrate 10 from the surface of the substrate 10, so that the first encapsulation layer 50 may also be filled between the second encapsulation body 30 and the surface of the substrate 10 while the first encapsulation layer 50 covers the edge 252 of the inner part the cavity, thereby improving the reliability of the product.

For example, a height h3 of the side surface of the second encapsulation body 30 facing the substrate from the surface of the substrate can be set in a range of 5 μm to 20 μm, and a height h1 of the side surface of the first encapsulating body 20 facing the substrate from the surface of the substrate may be set in a range of 10 μm to 40 μm.

In some embodiments, the second encapsulation body 30 may be an electronic component, where a size of the chip is much greater than that of the electronic component, which may be about ten times or more of the size of the electronic component, so that when the first encapsulation layer 50 is filled between the second encapsulation body 30 and the surface of the substrate 10, the first encapsulation layer is only positioned on the surface of the substrate 10 at the edge 252 of the inner part the cavity.

Specifically, the second encapsulation body 30 may be a transistor (such as a p-channel/n-channel metal oxide semiconductor field effect transistor (pMOSFET/nMOSFET), a bipolar junction transistor (BJT), a high-voltage transistor, a high-frequency transistor), a diode, a resistor, a capacitor, an inductor, a fuse, or other suitable components.

In other embodiments, the second encapsulation body 30 may be other types of chips that do not require to form a cavity with the substrate.

In some embodiments, the second connection structure 31 may include one or more of a metal ball, a metal bump, a metal pillar and the like, and the second connection structure is fixed to a pad on the surface of the substrate by soldering, so as to electrically connect the first encapsulation body 30 and the substrate 10. For a specific material of the metal ball, the metal bump and the metal pillar, refer to the existing descriptions.

In some embodiments, in order to make the height h1 of the side surface of the first encapsulation body facing the substrate from the surface of the substrate greater than the height h3 of the side surface of the second encapsulation body facing the substrate from the surface of the substrate, the height of the first connection structure may be set to be greater than the height of the second connection structure.

In some embodiments, the surface of the substrate 10 is provided with a second encapsulation body 30, and when the encapsulation layer 1 covers one side of the substrate provided with the first encapsulation body 20, the encapsulation layer 1 covers the second encapsulation body 30.

In some embodiments, when the encapsulation layer 1 covers the first encapsulation body 20 and the second encapsulation body 30, referring to FIG. 4, the encapsulation layer 1 includes a first encapsulation layer 50 positioned on the surface of the substrate 10 and a second encapsulation layer 60 positioned on the surface of the first encapsulation layer, and when the covering is performed by using a hot pressing process, the surface of the first encapsulation body 20 and the surface of the second encapsulation body 30 are also covered with the first encapsulation layer 50, so as to improve the bonding force between the encapsulation layer 1 and the first encapsulation body 20 and between the encapsulation layer and the second encapsulation body 30. Specifically, the side surface of the first encapsulation body 20 far away from the substrate and the side surface of the second encapsulation body 30 far away from the substrate are also covered with the first encapsulation layer 50, and the second encapsulation layer 60 is positioned on the surface of the first encapsulation layer 50.

In some embodiments, a material corresponding to the first encapsulation layer 50 has a fluidity greater than that of a material corresponding to the second encapsulation layer 60, the second encapsulation layer 60 has a thickness greater than that of the first encapsulation layer 50, and the first encapsulation layer 50 has a thin thickness, so that the entire encapsulation layer 1 has a low fluidity and is not easy to enter into the cavity, the encapsulation layer can be well covered on the surfaces of the substrate, the first encapsulation body and the second encapsulation body, and the bonding force between the encapsulation layer and the substrate, between the encapsulation layer and the first encapsulation body and between the encapsulation layer and the second encapsulation body can be enhanced. The first encapsulation layer 50 can be filled between the second encapsulation body 30 and the surface of the substrate 10 by using the fluidity of the material corresponding to the first encapsulation layer 50 and the thickness of the first encapsulation layer 50, so that the reliability of the product can be enhanced.

In some embodiments, the thickness h2 of the first encapsulation layer may be set to be greater than or equal to the height h3 of the side surface of the second encapsulation body facing the substrate from the surface of the substrate, so that the first encapsulation layer can be filled around the second connection structure between the second encapsulation body and the surface of the substrate.

In some embodiments, for example, when the height h3 of the side surface of the second encapsulation body facing the substrate from the surface of the substrate is in a range of 5 μm to 20 μm, the thickness of the first encapsulation layer can be set in a range of 5 μm to 20 μm, and the thickness of the second encapsulation layer is in a range of 200 μm to 500 μm.

In some embodiments, referring to FIG. 14, the surface of the encapsulation layer is further provided with an electromagnetic shielding layer 80 for electromagnetic shielding and protection. The electromagnetic shielding layer 80 may include a first stainless steel layer positioned on the surface of the encapsulation layer, a copper layer positioned on the surface of the first stainless steel layer, and a second stainless steel layer positioned on the surface of the copper layer; where a thickness of the stainless steel layer can be set to about 0.1 μm, a thickness of the copper layer can be set to about 3 μm to 7 μm, and a thickness of the second stainless steel layer can be set to about 0.1 μm.

However, in other embodiments, the surface of the encapsulation layer 1 may not be provided with the electromagnetic shielding layer 80 based on different package types.

According to the package structure provided by the embodiment, the traditional packaging process can be used without new equipment, so that the packaging cost is low, and the operation performance is good. In addition, the bonding force between the encapsulation layer and the product is high, and the product reliability is high.

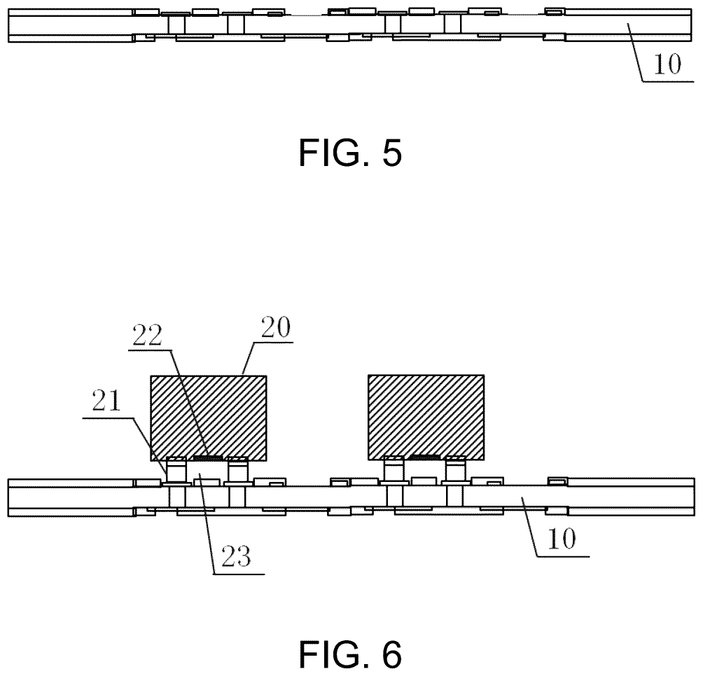

In some embodiments, a preparation method of a package structure with a cavity is further provided, which includes:
referring to FIG. 5, providing a substrate 10;
referring to FIG. 6, arranging a first encapsulation body 20 on the surface of the substrate 10 through a first connection structure 21;
referring to FIGS. 7 to 8, covering an encapsulation layer 1 on one side of the substrate 10 provided with the first encapsulation body 20, so that a cavity 23 is formed between the first encapsulation body 20 and the substrate 10;
where the encapsulation layer 1 includes a first encapsulation layer 50 positioned on the surface of the substrate 10 and a second encapsulation layer 60 positioned on a surface of the first encapsulation layer 50 and covering the first encapsulation body 20; and
a material corresponding to the first encapsulation layer 50 has a fluidity greater than that of a material corresponding to the second encapsulation layer 60, so that the first encapsulation layer 50 is positioned on an edge 252 of an inner part of the cavity and the surface of the substrate of an outer part 251 of the cavity, and the second encapsulation layer 60 is positioned on the surface of the first encapsulation layer 50 of the outer part 251 of the cavity.

In some embodiments, the covering an encapsulation layer 1 on one side of the substrate 10 provided with the first encapsulation body 20 includes:
referring to FIG. 7, placing the encapsulation layer 1 into a mold 70, and when the encapsulation layer 1 is in a fluid state, pressing the first encapsulation body 20 arranged on the substrate 10 into the encapsulation layer 1 facing the first encapsulation layer 50; and
referring to FIG. 8, after the first encapsulation layer 50 reaches the surface of the substrate 10, forming a state as shown in the figure, and curing the encapsulation layer 1, thereby forming the encapsulation layer 1 covering one side of the substrate 10 provided with the first encapsulation body 20.

In some embodiments, the placing the encapsulation layer 1 into a mold 70 may be as follows: placing a second encapsulation layer 60 in a mold 70, and placing a first encapsulation layer 50 on a surface of the second encapsulation layer 60 in the mold 70.

In some embodiments, the first encapsulation layer 50 and the second encapsulation layer 60 may be made of different materials or the same material, so that the material preparation and the material development time can be reduced.

In some embodiments, when the first encapsulation layer 50 and the second encapsulation layer 60 are made of the same material, a change rule of the viscosity of the encapsulant can be used, that is, the viscosity of the encapsulant is high at first, becomes low after heating and maintains low for a period of time, and is increased due to a glue chain reaction after continued heating.

The second encapsulation layer 60 is firstly placed in a mold cavity of the mold 70, the first encapsulation layer 50 is placed when the viscosity of the second encapsulation layer 60 is reduced after being heated, the heating is continued, the product is placed when the viscosity of the second encapsulation layer 60 is increased again due to a glue chain reaction and the viscosity of the first encapsulation layer 50 is reduced after being heated, and encapsulation is performed, so that the first encapsulation layer 50 after encapsulation is positioned on the edge 252 of the inner part of the cavity and the surface of the substrate of the outer part 251 of the cavity, and the second encapsulation layer 60 is positioned on the surface of the first encapsulation layer 50 of the outer part 251 of the cavity, thereby improving the bonding force by increasing the contact area with the substrate.

In some embodiments, when the material corresponding to the encapsulation layer 1 is a thermosetting encapsulant, the encapsulant needs to be heated to enable the encapsulation layer 1 to be in a fluid state. In other embodiments, the encapsulation layer 1 in the fluid state can also be directly provided.

In some embodiments, the heat treatment is performed on the encapsulation layer in the following heating conditions, for example, at a temperature of 40° C. to 100° C. and a pressure of 0.1 MPa to 10 MPa for 0.3 minutes to 10 minutes, to enable the encapsulation layer 1 to be in a fluid state. In addition, if the improvement of the adhesion and followability between the encapsulation layer and the substrate is considered, the pressing may be performed under reduced pressure (0.1 kPa to 5 kPa).

In some embodiments, curing the encapsulation layer 1 may be performed in the following heating conditions, for example, the heating temperature may be 100° C. or more and may have an upper limit of 200° C. or less, and the heating time may be 10 minutes or more and may have an upper limit of 180 minutes or less; in addition, the pressurization may be performed based on a requirement, which may be 0.1 MPa or more and may have an upper limit of 10 MPa or less.

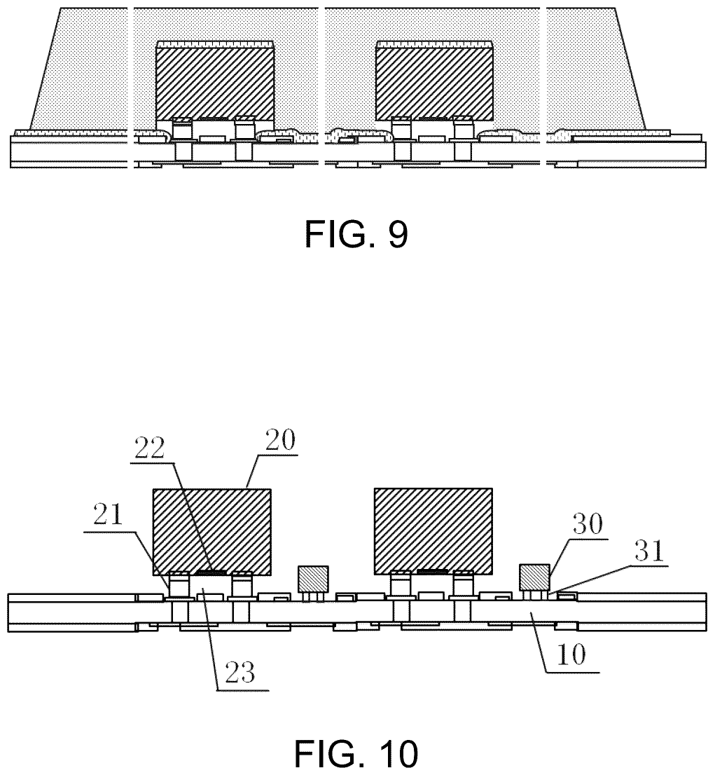

In some embodiments, after forming the encapsulation layer, the method further includes:
printing a pattern on the surface of the encapsulation layer; and
referring to FIG. 9, performing cutting based on a cutting process to obtain a single package structure including the first encapsulation body 20 as shown in FIG. 3.

In some embodiments, after providing a substrate, and before covering an encapsulation layer on one side of the substrate provided with the first encapsulation body, the method further includes:
referring to FIG. 10, arranging a second encapsulation body 30 on the surface of the substrate 10 through a second connection structure 31;
where an area of one side surface 24 of the first encapsulation body 20 facing the substrate 10 is greater than that of one side surface 32 of the second encapsulation body 30 facing the substrate 10, and a height h1 of one side surface of the first encapsulation body 20 facing the substrate 10 from the surface of the substrate 10 is greater than or equal to a height h3 of one side surface of the second encapsulation body 30 facing the substrate 10 from the surface of the substrate 10, so that the first encapsulation layer 50 is filled between the second encapsulation body 30 and the surface of the substrate 10, and the first encapsulation layer 50 is filled between the second encapsulation body 30 and the surface of the substrate 10 when the encapsulation layer 1 is formed later.

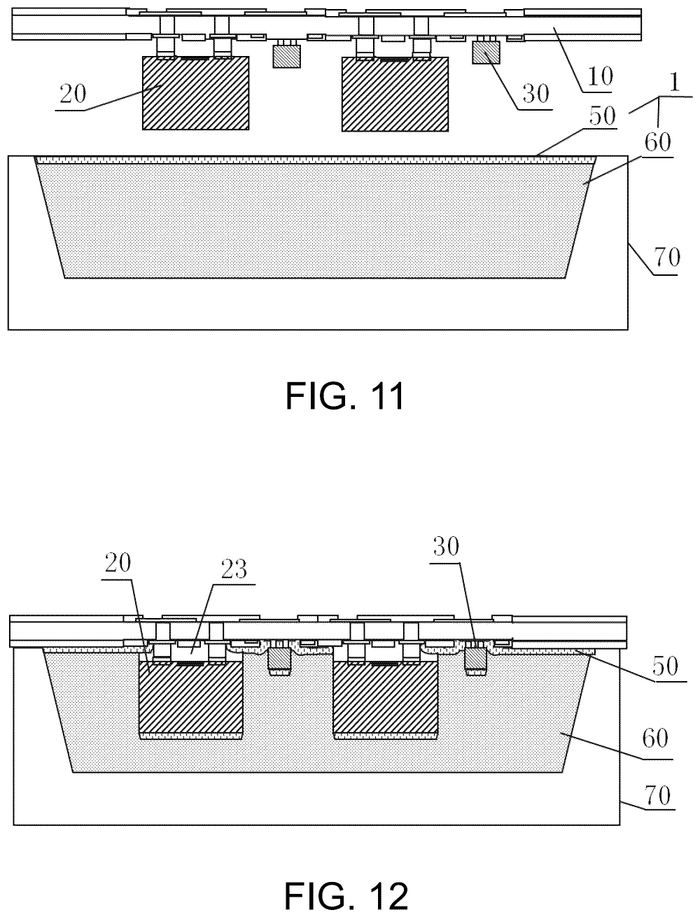

Referring to FIGS. 11 to 12, the covering an encapsulation layer 1 on one side of the substrate 10 provided with the first encapsulation body 20 includes:
covering the encapsulation layer 1 on the substrate 10 provided with the first encapsulation body 20 and the second encapsulation body 30.

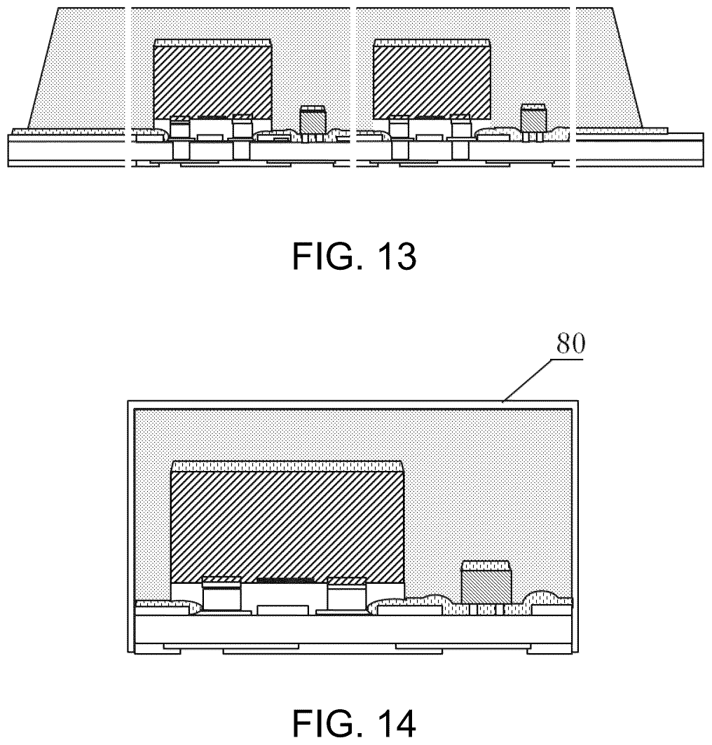

In some embodiments, after forming the encapsulation layer 1, the method further includes:
printing a pattern on the surface of the encapsulation layer; and
referring to FIG. 13, performing cutting based on a cutting process to obtain a single package structure including the first encapsulation body 20 and the second encapsulation body 30.

In some embodiments, after obtaining the single package structure, referring to FIG. 14, the method further includes: forming an electromagnetic shielding layer 80 on a surface of an encapsulation layer 1 of the single package structure.
The present disclosure has been described with reference to the preferred embodiment, which is not intended to be limited thereto. Those skilled in the art can make possible variations and modifications to the present disclosure using the disclosed methods and technical contents without departing from the spirit and scope of the present disclosure; and therefore, any simple modifications, equivalent changes and modifications made to the above embodiments according to the technical spirit of the present disclosure without departing from the content of the technical solutions of the present disclosure shall fall within the protection scope of the technical solutions of the present disclosure.

What is claimed is:

1. A package structure with a cavity, comprising:
a substrate;
a first encapsulation body arranged on a surface of the substrate through a first connection structure;
an encapsulation layer covering a side of the substrate provided with the first encapsulation body;
wherein the cavity is provided between the first encapsulation body and the substrate, and the encapsulation layer comprises a first encapsulation layer positioned on the surface of the substrate and a second encapsulation layer positioned on a surface of the first encapsulation layer and covering the first encapsulation body; and
a material related to the first encapsulation layer has a fluidity greater than that of a material related to the second encapsulation layer, so that the first encapsulation layer is positioned on an edge of an inner part of the cavity as well as the surface of the substrate outside the cavity, and the second encapsulation layer is positioned on the surface of the first encapsulation layer outside the cavity.

2. The package structure with the cavity according to claim 1, wherein the first encapsulation layer has a thickness less than or equal to a height of a surface of a side of the first encapsulation body facing the substrate from the surface of the substrate.

3. The package structure with the cavity according to claim 1, further comprising:
a second encapsulation body arranged on the surface of the substrate through a second connection structure;
wherein an area of a surface of a side of the first encapsulation body facing the substrate is greater than that of a surface of a side of the second encapsulation body facing the substrate, a height of the surface of the side of the first encapsulation body facing the substrate from the surface of the substrate is greater than or equal to a height of the surface of the side of the second encapsulation body facing the substrate from the surface of the substrate, and the first encapsulation layer is fully filled between the second encapsulation body and the surface of the substrate.

4. The package structure with the cavity according to claim 3, wherein the first encapsulation layer has a thickness greater than or equal to the height of the surface of the side of the second encapsulation body facing the substrate from the surface of the substrate.

5. The package structure with the cavity according to claim 3, wherein the first encapsulation body is a chip, and the second encapsulation body is an electronic component.

6. The package structure with the cavity according to claim 3, wherein both the first connection structure and the second connection structure are metal pillars.

7. The package structure with the cavity according to claim 1, wherein a surface of a side of the first encapsulation body facing the substrate is provided with a sensing area, and the cavity is provided between the sensing area and the surface of the substrate.

8. The package structure with the cavity according to claim 7, wherein the sensing area is positioned in a middle area of the surface of the side of the first encapsulation body facing the substrate.

9. The package structure with the cavity according to claim 1, further comprising:
an electromagnetic shielding layer arranged on a surface of the encapsulation layer.

10. A preparation method of a package structure with a cavity, comprising:
providing a substrate;
arranging a first encapsulation body on a surface of the substrate through a first connection structure;
covering an encapsulation layer on a side of the substrate provided with the first encapsulation body so that the cavity is formed between the first encapsulation body and the substrate;
wherein the encapsulation layer comprises a first encapsulation layer positioned on the surface of the substrate and a second encapsulation layer positioned on a surface of the first encapsulation layer and covering the first encapsulation body; and a material related to the first encapsulation layer has a fluidity greater than that of a material related to the second encapsulation layer, so that the first encapsulation layer is positioned on an edge of an inner part of the cavity as well as the surface of the substrate outside the cavity, and the second encapsulation layer is positioned on the surface of the first encapsulation layer outside the cavity.

11. The preparation method of the package structure with the cavity according to claim 10, wherein the first encapsulation layer has a thickness less than or equal to a height of a surface of a side of the first encapsulation body facing the substrate from the surface of the substrate.

12. The preparation method of the package structure with the cavity according to claim 10, wherein after providing the substrate, and before covering the encapsulation layer on the side of the substrate provided with the first encapsulation body, the method further comprises:
arranging a second encapsulation body on the surface of the substrate through a second connection structure;
wherein an area of a surface of a side of the first encapsulation body facing the substrate is greater than that of a surface of a side of the second encapsulation body facing the substrate, a height of the surface of the side of the first encapsulation body facing the substrate from the surface of the substrate is greater than or equal to a height of the surface of the side of the second encapsulation body facing the substrate from the surface of the substrate, and the first encapsulation layer is fully filled between the second encapsulation body and the surface of the substrate while the encapsulation layer is being formed in a later step.

13. The preparation method of the package structure with the cavity according to claim 12, wherein the first encapsulation layer has a thickness greater than or equal to the height of the surface of the side of the second encapsulation body facing the substrate from the surface of the substrate.

14. The preparation method of the package structure with the cavity according to claim 12, wherein the first encapsulation body is a chip, and the second encapsulation body is an electronic component.

15. The preparation method of the package structure with the cavity according to claim 10, wherein a surface of a side of the first encapsulation body facing the substrate is provided with a sensing area, and the cavity is provided between the sensing area and the surface of the substrate.

16. The preparation method of the package structure with the cavity according to claim 10, wherein covering the encapsulation layer on the side of the substrate provided with the first encapsulation body comprises:
when the encapsulation layer is in a fluid state, the first encapsulation body arranged on the substrate toward the first encapsulation layer and pressing it into the encapsulation layer; and
curing the encapsulation layer after the first encapsulation layer reaches the surface of the substrate, thereby forming the encapsulation layer that covers the side of the substrate provided with the first encapsulation body.

17. The preparation method of the package structure with the cavity according to claim 10, wherein after the encapsulation layer is formed, the method further comprises:
performing cutting based on a cutting process to obtain a single package structure.

18. The preparation method of the package structure with the cavity according to claim 17, wherein after the single package structure is obtained, the method further comprises:
forming an electromagnetic shielding layer on a surface of the encapsulation layer of the single package structure.
